(19) United States
(12) Patent Application Publication
(10) Pub. No.: US 2026/0075995 A1
(43) Pub. Date: Mar. 12, 2026

(54) LIGHT EMITTING DEVICE

(71) Applicant: Seoul Semiconductor Co., Ltd., Ansan-si (KR)

(72) Inventor: Myung Jin KIM, Ansan-si (KR)

(73) Assignee: Seoul Semiconductor Co., Ltd., Ansan-si (KR)

(21) Appl. No.: 19/317,504

(22) Filed: Sep. 3, 2025

Related U.S. Application Data
(60) Provisional application No. 63/693,112, filed on Sep. 10, 2024.

(51) Int. Cl. H10H 20/851; H10H 29/851

(52) U.S. Cl. CPC H10H 20/8514; H10H 29/8514

(57) ABSTRACT

A light emitting apparatus including: a substrate; a light-emitting source disposed on the substrate and configured to emit light; and a light-absorbing filler that absorbs light such that when an output spectrum is calculated based on a spectrum of light emitted from the light-emitting source and a preset setting function, a ratio of an area of a specific reference wavelength range in the output spectrum to an area of an entire wavelength range in the output spectrum is less than or equal to a threshold value.

### CROSS-REFERENCE TO RELATED APPLICATIONS

This application claims the benefit of U.S. Provisional Application No. 63/693,112 filed May 15, 2019, the entire contents of which is incorporated herein by reference.

### TECHNICAL FIELD

The present disclosure relates to a light emitting apparatus.

### BACKGROUND

A light emitting apparatus can emit light to display characters, symbols, images, or videos on a display.

The light emitting apparatus includes a light-emitting surface from which light is emitted, and when light is evenly emitted from the entire light-emitting surface, the characters, symbols, images, or videos displayed on the display can be displayed more clearly. In other words, the higher the surface emission efficiency of the light emitting apparatus, the clearer the characters, symbols, images, or videos displayed on the display can be displayed.

Recently, concerns have been raised regarding visual fatigue, disturbance of biorhythms, and potential retinal damage caused by short-wavelength light. Accordingly, there is a growing need for a light emitting apparatus having optimized emission characteristics within a predetermined wavelength range.

### SUMMARY

Embodiments of the disclosed technology may provide a light emitting apparatus capable of efficiently absorbing light in a specific wavelength range.

Embodiments of the disclosed technology may provide a high-quality light emitting apparatus by improving color brightness and color reproducibility.

Embodiments of the disclosed technology may provide a high-quality light emitting apparatus by increasing color contrast.

Embodiments of the disclosed technology may provide a light emitting apparatus with improved reliability by absorbing high-energy light and reducing yellowing or light damage caused by light.

Embodiments of the disclosed technology may provide a light emitting apparatus with improved blue light hazard characteristics.

Embodiments of the disclosed technology may provide a high quality light emitting apparatus with improved color reproducibility.

In one aspect, there may be provided a light emitting apparatus comprising: a substrate; a light-emitting source disposed on the substrate and configured to emit light; and a light-absorbing filler that absorbs light such that when an output spectrum is calculated based on a spectrum of light emitted from the light-emitting source and a preset setting function, a ratio of an area of a predetermined reference wavelength range in the output spectrum to an area of an entire wavelength range in the output spectrum is less than or equal to a threshold value, wherein the predetermined reference wavelength range has a lower limit value smaller than a peak wavelength of the output spectrum, and an upper limit value greater than the peak wavelength of the output spectrum.

Further, there may be provided the light emitting apparatus where the threshold value is 10% to 15%.

Further, there may be provided the light emitting apparatus where the area of the entire wavelength range is calculated based on the following Equation 1.

$$Area of entire wavelength range = {\sum }_{a}^{b} {Φ}_{λ} \cdot B ( λ ) \cdot Δλ \qquad ( Equation 1 )$$

(where, λ represents a wavelength, Φ_{λ} represents the spectral intensity of light emitted from the light-emitting source, B(λ) represents a light spectrum hazard function that is the setting function, a is a first wavelength which is the smallest in the entire wavelength range, and b is a second wavelength which is the largest in the entire wavelength range.)

Further, there may be provided the light emitting apparatus where the area of the reference wavelength range is calculated based on the following Equation 2.

$$Area of reference wavelength range = {\sum }_{c}^{d} {Φ}_{λ} \cdot B ( λ ) \cdot Δλ \qquad ( Equation 2 )$$

(where, λ represents the wavelength, Φ_{λ} represents the spectrum of light emitted from the light-emitting source, B(λ) represents the light spectrum hazard function, c is a first reference wavelength, and d is a second reference wavelength.)

Further, there may be provided the light emitting apparatus where the area of the reference wavelength range and the area of the entire wavelength range satisfies the following Equation 3.

$$y = \frac{{\sum }_{c}^{d} {Φ}_{λ} \cdot B ( λ ) \cdot Δ λ}{{\sum }_{a}^{b} {Φ}_{λ} \cdot B ( λ ) \cdot Δ λ} \leq 10 \% \qquad ( Equation 3 )$$

(where, y represents a ratio of the area of the reference wavelength range to the area of the entire wavelength range.)

Further, there may be provided the light emitting apparatus where the first wavelength is 380 nm, and the second wavelength is 780 nm.

Further, there may be provided the light emitting apparatus where the second wavelength is 430 nm.

Further, there may be provided the light emitting apparatus where a peak wavelength of the setting function is greater than a peak wavelength of the spectrum of light emitted from the light-emitting source.

Further, there may be provided the light emitting apparatus further including: a wavelength converter supported on the substrate to cover the light-emitting source; and a light-transmitting layer disposed on at least one region of the wavelength converter.

Further, there may be provided the light emitting apparatus where the light-absorbing filler is disposed in at least one of the wavelength converter and the light-transmitting layer.

Further, there may be provided the light emitting apparatus where the wavelength converter and the light-transmitting layer are arranged to be spaced apart from each other in an up-down direction.

In one aspect, there may be provided the light emitting apparatus where the light-emitting source is provided as a plurality of light-emitting sources, and the plurality of light-emitting sources include: a first light-emitting source that emits blue light; and a second light-emitting source that emits green light.

In one aspect, there may be provided a light emitting apparatus comprising: a substrate including a base and a sidewall extending upward from an edge of the base; a light-emitting source supported on the substrate and configured to emit light; a molding part covering the light-emitting source; a wavelength converter disposed in at least one region of the molding part and at least one region of the sidewall to convert a wavelength of light; and a light-absorbing filler disposed in the molding part and the wavelength converter to absorb a portion of the light.

Further, there may be provided the light emitting apparatus where the light-emitting source is provided as a plurality of light-emitting sources, and the plurality of light-emitting sources include: a first light-emitting source that emits blue light; a second light-emitting source that emits green light; and a third light-emitting source that emits red light.

In one aspect, there may be provided a light emitting apparatus comprising: a substrate including a base and a sidewall extending upward from an edge of the base; a light-emitting source supported on the substrate and configured to emit light; a molding part covering the light-emitting source; a light-transmitting layer disposed in at least one region of the molding part to transmit light; and a light-absorbing filler disposed in the light-transmitting layer to absorb a portion of the light.

Further, there may be provided the light emitting apparatus where the molding part and the light-transmitting layer are arranged to be spaced apart from each other in an up-down direction.

Further, there may be provided the light emitting apparatus further including: a wavelength converter supported on the molding part and the sidewall to be positioned between the molding part and the light-transmitting layer and configured to convert a wavelength of light.

Further, there may be provided the light emitting apparatus where the light-transmitting layer and the wavelength converter are arranged to be spaced apart from each other in the up-down direction.

Further, there may be provided the light emitting apparatus further including a wavelength converter covering an upper surface of the base and the light-emitting source so that the upper surface of the base and the light-emitting source are spaced apart from the molding part.

Further, there may be provided the light emitting apparatus where the light-emitting source is provided as a plurality of light-emitting sources, and the plurality of light-emitting sources include: a first light-emitting source that emits blue light; a second light-emitting source that emits green light; and a third light-emitting source that emits red light.

Embodiments of the disclosed technology may provide a light emitting apparatus with increased optical safety by reducing light in a wavelength range that may be harmful to the human body.

Embodiments of the disclosed technology may provide a high-quality light emitting apparatus by improving color brightness and color reproducibility.

Embodiments of the disclosed technology may provide a high-quality light emitting apparatus by increasing color contrast.

Embodiments of the disclosed technology may provide a light emitting apparatus with improved reliability by absorbing high-energy light and reducing yellowing or light damage caused by light.

Embodiments of the disclosed technology may provide a light emitting apparatus with improved reliability by improving damage caused by heat.

Embodiments of the disclosed technology may provide a light emitting apparatus with high light output by improving phosphor-converted light extraction efficiency.

### BRIEF DESCRIPTION OF THE DRAWINGS

FIG. 1 is a diagram showing the appearance of a light emitting apparatus according to a first embodiment of the present disclosure.

FIG. 2 is a diagram showing the appearance of a light-absorbing filler of the light emitting apparatus of FIG. 1.

FIG. 3 is a diagram showing the appearance of a light emitting apparatus according to a second embodiment of the present disclosure in which a light-transmitting layer is disposed on at least one region of a wavelength converter.

FIG. 4 is a diagram showing the appearance of the light emitting apparatus according to the second embodiment of the present disclosure in which the light-transmitting layer and a wavelength converter are arranged to be spaced apart from each other.

FIG. 5 is a diagram showing the appearance of a light emitting apparatus according to a third embodiment of the present disclosure in which a light-absorbing filler is arranged in a molding part.

FIG. 6 is a diagram showing the appearance of the light emitting apparatus according to the third embodiment of the present disclosure in which the light-absorbing filler is arranged in a wavelength converter.

FIG. 7 is a diagram showing the appearance of a light emitting apparatus according to a fourth embodiment of the present disclosure in which a light-absorbing filler is disposed in a light-transmitting layer.

FIG. 8 is a diagram showing the appearance of the light-transmitting device according to the fourth embodiment of the present disclosure in which the light-transmitting layer and a wavelength converter are arranged to be spaced apart from each other.

FIG. 9 is a diagram showing the wavelength converter of the light emitting apparatus according to the fourth embodiment of the present disclosure, wherein the wavelength converter is arranged below a molding part.

FIG. 10 is a diagram showing an example of the spectrum of light of the light emitting apparatus according to the second to fourth embodiments of the present disclosure.

FIG. 11 is a diagram showing a light emitting apparatus according to a fifth embodiment of the present disclosure, wherein a wavelength converter covers a first light-emitting source and a second light-emitting source.

FIG. 12 is a diagram showing a light-transmitting layer disposed on at least one region of the wavelength converter of the light emitting apparatus according to the fifth embodiment of the present disclosure.

FIG. 13 is a diagram showing the wavelength converter and the light-transmitting layer of a light emitting apparatus according to the fifth embodiment of the present disclosure, wherein they are arranged spaced apart from each other.

FIG. 14 is a diagram showing an example of the spectrum of light emitted from the light emitting apparatus according to the fifth embodiment of the present disclosure.

FIG. 15 is a diagram showing a light emitting apparatus according to a sixth embodiment of the present disclosure, wherein a molding part covers a first light-emitting source, a second light-emitting source, and a third light-emitting source.

FIG. 16 is a diagram showing a state in which a light-absorbing filler is arranged in a light-transmitting layer in the light emitting apparatus according to the sixth embodiment of the present disclosure.

FIG. 17 is a diagram showing a state in which the light-transmitting layer and the molding part of a light emitting apparatus according to the sixth embodiment of the present disclosure are arranged spaced apart from each other.

FIG. 18 is an example of a spectrum of light emitted from the light emitting apparatus according to the sixth embodiment.

FIG. 19 is a diagram showing a graph in which a light spectrum of the light emitting apparatus according to one embodiment of the present disclosure is multiplied by a light spectrum hazard function.

FIG. 20 is a schematic diagram for explaining a display device equipped with a light emitting apparatus 1 according to one embodiment of the present disclosure.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, the specific configuration of a light emitting apparatus 1 according to a first embodiment of the present disclosure will be described with reference to the drawings.

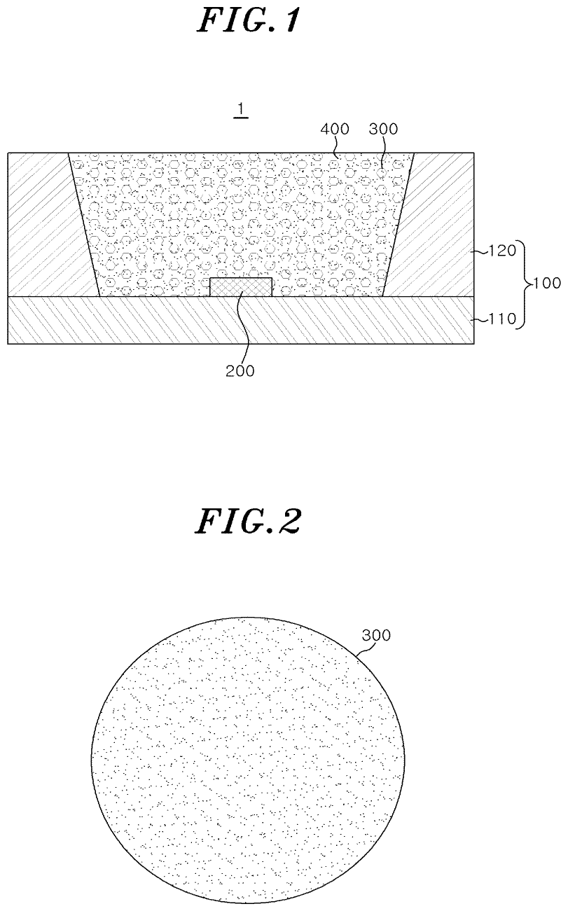

Referring to FIGS. 1 and 2, the light emitting apparatus 1 according to the first embodiment of the present disclosure can receive power from an external source and emit light. The light emitting apparatus 1 may be applied to a light emitting apparatus such as a display. The light emitting apparatus 1 may include a substrate 100, a light-emitting source 200, a light-absorbing filler 300, and a wavelength convertor 400.

The substrate 100 may support at least one of the light-emitting source 200 and the wavelength converter 400. For example, the substrate 100 may be a printed circuit board (PCB). In addition, the substrate 100 may include at least one of Cu, Zn, Au, Ni, Al, Mg, Cd, Be, W, Mo, Si, Ag or Fe, or an alloy composed of some of these. However, this is merely an example, and the substrate 100 may also include at least one of an insulating material such as a ceramic series such as FR1, CEM-1, FR-4, Al₂O₃ or AlN, a PMMA (polymethyl methacrylate) series, a PE (polyethylene) series, or a PS (polystyrene) series. In this case, FR1 is a material in which copper foil and laminated paper are laminated, and CEM-1 is a material in which copper foil, glass fiber fabric, laminated paper, and glass fiber fabric are sequentially laminated. In addition, FR-4 is a material in which copper foil and glass fiber fabric or glass fiber fabric are laminated. In addition, the substrate 100 may include a base 110 and a sidewall 120.

The base 110 may support the light-emitting source 200. In other words, the base 110 and the light-emitting source 200 may be electrically connected. In addition, a wavelength converter 400 may be disposed on at least a portion of the base 110.

The sidewall 120 may extend upward from the base 110 at the edge of the base 110 and provide an accommodation space for accommodating the light-emitting source 200 at the inside thereof. The sidewall 120 may extend to surround at least a portion of the light-emitting source 200. The sidewall 120 may be formed to have a height greater than a height of the light-emitting source 200. The sidewall 120 can reflect light emitted from the light-emitting source 200.

The light-emitting source 200 can emit light. For example, the light-emitting source 200 may be a device that converts electric energy into light, such as a light emitting diode, a laser diode, or an organic light emitting diode. In this case, the light-emitting source 200 can emit ultraviolet light, blue light, green light, yellow light, red light, infrared light, etc. The light-emitting source 200 is electrically connected to an electric circuit of a substrate 100 and can receive electricity from an external source through the electric circuit to emit light. The light-emitting source 200 may be configured as any one of a flip chip, a lateral chip, or a vertical chip.

The light-absorbing filler 300 may be a particle or pellet for absorbing a portion of the light emitted from the light-emitting source 200. The light-absorbing filler 300 may be disposed in the wavelength converter 400. For example, the light-absorbing filler 300 may absorb specific wavelengths of light, such as short-wavelength UV light, short-wavelength blue light, and ling-wavelength infrared light, but the present disclosure is not limited thereto. In other words, referring to FIG. 19 to be described later, the light-absorbing filler 300 may absorb light such that when an output spectrum is calculated based on the spectrum of light emitted from the light-emitting source 200 and a preset setting function, a ratio of the area of a specific reference wavelength range in the output spectrum to the area of the entire wavelength range in the output spectrum is less than or equal to a threshold value. For example, the threshold value may be 10 to 15%. The peak wavelength of the setting function may be greater than the peak wavelength of the spectrum of light emitted from the light-emitting source 200. The reference wavelength range may have a lower limit value smaller than the peak wavelength of the calculated spectrum and an upper limit value greater than the peak wavelength of the calculated spectrum.

The area of the entire wavelength range can be calculated based on the following Equation 1.

$$Area of entire wavelength range = {\sum }_{a}^{b} {Φ}_{λ} \cdot B ( λ ) \cdot Δλ \qquad [ Equation 1 ]$$

In Equation 1, λ represents a wavelength Φ_{λ} represents a spectrum of light emitted from the light-emitting source 200, and B(λ) represents a setting function which is a light spectrum hazard function. In addition, a is a first wavelength which is the smallest in the entire wavelength range, b is a second wavelength which is the largest in the entire wavelength range, and λ is a wavelength. For example, the first wavelength may be 380 nm, and the second wavelength may be 780 nm. In other words, the entire wavelength range of the output spectrum may be 380 to 780 nm, but it is not limited thereto.

Data for B(λ) sampled at 10 nm intervals are shown in Table 1 below.

TABLE 1

| WL(nm) | B(λ) |
|---|---|
| 380 | 1% |
| 390 | 3% |
| 400 | 10% |
| 410 | 40% |
| 420 | 90% |
| 430 | 98% |
| 440 | 100% |
| 450 | 94% |
| 460 | 80% |
| 470 | 62% |
| 480 | 45% |
| 490 | 22% |
| 500 | 10% |
| 510 | 6% |
| 520 | 4% |
| 530 | 3% |
| 540 | 2% |
| 550 | 1% |
| 560 | 1% |

The area of the reference wavelength range from reference wavelength e to reference wavelength d can be calculated based on the following Equation 2.

$$Area of reference wavelength range = {\sum }_{c}^{d} {Φ}_{λ} \cdot B ( λ ) \cdot Δλ \qquad [ Equation 2 ]$$

In Equation 2, λ represents a wavelength. Φ_{λ} represents a spectrum of light emitted from the light-emitting source 200, B(λ) represents a light spectrum hazard function, c is a first reference wavelength, d is a second reference wavelength which may be a wavelength between the first wavelength and the second wavelength. The c may correspond to a start point of the spectrum of light emitted from the light-emitting source 200, and the d may correspond to an end point of the spectrum of light emitted from the light-emitting source 200, and may be smaller than the second wavelength in the entire spectrum. The c and d may have intensities less than 2% of the peak intensity of the light emitted from the light-emitting source 200. The c may be located in the shorter-wavelength region than the peak wavelength, and the value d may be located in the longer-wavelength region than the peak wavelength. The first reference wavelength may be 380 nm to be the same as the first wavelength. The second reference wavelength may be 430 nm. In other words, the reference wavelength range of the output spectrum may be 380 to 430 nm, but it is not limited thereto. B(λ) may be an ocular stability function for the blue light region, but the present disclosure is not limited thereto. Alternatively, B(λ) may be a luminous efficiency function for a target wavelength range.

In addition, the area of the reference wavelength range and the area of the entire wavelength range in the output spectrum can satisfy the following Equation 3.

$$y = \frac{{\sum }_{c}^{d} {Φ}_{λ} \cdot B ( λ ) \cdot Δ λ}{{\sum }_{a}^{b} {Φ}_{λ} \cdot B ( λ ) \cdot Δ λ} \leq 10 \% \qquad [ Equation 3 ]$$

In Equation 3, y represents the ratio of the area of the reference wavelength range to the area of the entire wavelength range. In other words, the area of the reference wavelength range may be less than 10% of the area of the entire wavelength range. More preferably, the area of the reference wavelength range may be less than 5% of the area of the entire wavelength range. y may be the blue light hazard level.

Since the light-absorbing filler 300 can absorb light in the reference wavelength range, the safety of light emitted from the light-emitting source 200 can be improved. In other words, the light-absorbing filler 300 can absorb light in a wavelength range that may be harmful to a user's body. In addition, the light-absorbing filler 300 enables the implementation of the light emitting apparatus 1 with improved stability that satisfies Equation 3. The light-absorbing filler 300 may absorb light in the reference wavelength range to reduce the intensity of light that is harmful to the human body. The light-absorbing filler 300 may also absorb light in the reference wavelength range and convert it into light of a different wavelength range. The light-absorbing filler 300 may include, e.g., pigments such as cobalt oxide-containing pigments, benzimidazolone-based pigments, and carbazole dioxazine-based pigments; fillers including oxides such as Fe₂O₃, TiO₂, ZnO, and Nd₂O₃; yellow/amber/red dyes; quantum dots; and nanophosphors.

The wavelength converter 400 may be disposed in the accommodation space of the sidewall 120 to cover the light-emitting source 200, and the wavelength converter 400 can enhance the light extraction efficiency of the light-emitting source 200. In addition, the wavelength converter 400 may encapsulate the light-emitting source 200 and refract light emitted from the light-emitting source 200. Further, the wavelength converter 400 may be a light-transmitting transparent molding for transmitting light emitted from the light-emitting source 200. For example, the wavelength converter 400 may be formed of a resin including at least one of a silicone series or an epoxy series, and may also be formed of an inorganic material such as a glass series or a ceramic series. In addition, the wavelength converter 400 may also be formed of a fluorine resin for improving the efficiency of light emitted from a plurality of light-emitting sources 200.

The wavelength converter 400 may include a wavelength-converting material capable of converting the wavelength of light emitted from the light-emitting source 200. For example, the wavelength-converting material may include a phosphor material capable of emitting one or more of red light, blue light, or green light.

In addition, the wavelength converter 400 may include a light-diffusing material capable of diffusing light emitted from the light-emitting source 200. For example, the light-diffusing material may include one or more of TiO₂, BaO, SiO₂, and MgO, Y₂O₃ capable of scattering light.

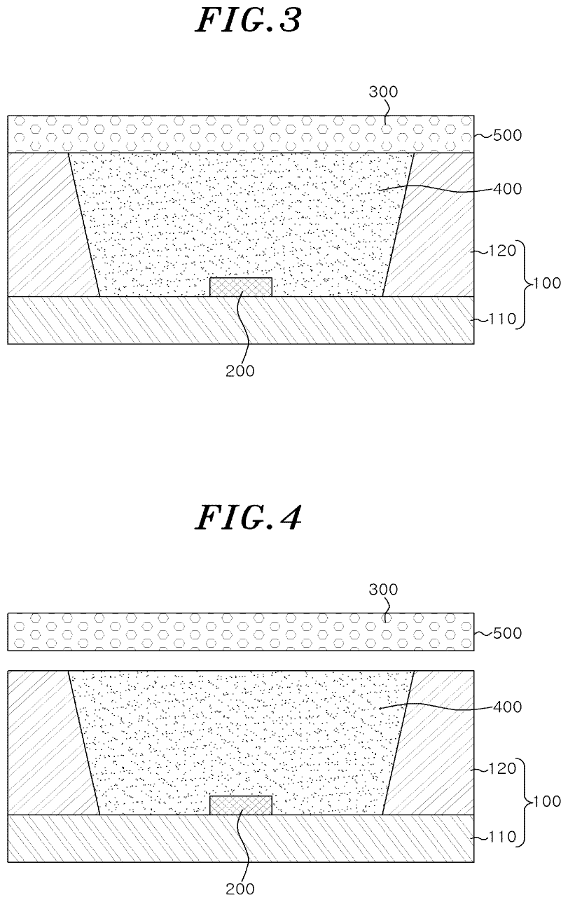

Hereinafter, a light emitting apparatus 1 of a second embodiment of the present disclosure will be described with reference to FIGS. 3 and 4. In describing the second embodiment, there is a difference in that a light-transmitting layer 500 may be further included, and the following description will focus on this difference.

The light-transmitting layer 500 may be disposed in at least one region of the wavelength converter 400 so that light emitted from the light-emitting source 200 can be transmitted therethrough. The light-transmitting layer 500 can diffuse light. For example, the light-transmitting layer 500 may be laminated on at least one region of the wavelength converter 400 or may be disposed to be spaced apart from the wavelength converter 400 in one direction. When the light-transmitting layer 500 and the wavelength converter 400 are spaced apart from each other, an air layer is formed between the light-transmitting layer 500 and the wavelength converter 400, which reduces damage due to heat and improves reliability. However, the present disclosure is not limited thereto, and a separate light-transmitting layer may be further provided between the light-transmitting layer 500 and the wavelength converter 400 to adjust the optical path. The light-transmitting layer 500 may be a light transmitting transparent molding for transmitting light emitted from the light-emitting source 200, and may be formed of a resin including at least one of a silicone series, an epoxy series, and a fluorine resin, for example. Further, the light-transmitting layer 500 may be formed of glass or ceramic for improving the efficiency of light emitted from the light-emitting source 200. In addition, the light-transmitting layer 500 may have a convex or concave lens shape with a curved surface for controlling the light emission angle. Furthermore, the light-transmitting layer 500 may be manufactured in a flat shape so as not to obstruct the optical path. In addition, the light-transmitting layer 500 may have a thickness lower than that of the sidewall 120 to minimize light absorption.

The light-absorbing filler 300 may be disposed in the light-transmitting layer 500 and disposed in a region farther away from the light-emitting source 200 than the wavelength converter 400. In other words, light can transmit through the light-transmitting layer 500 in which the light-absorbing filler 300 is disposed after transmitting through the wavelength converter 400, which reduces light loss. The light-absorbing filler 300 may be disposed in the light-transmitting layer 500 to absorb light in a wavelength range that may be harmful to a user's body. In other words, the light-absorbing filler 300 enables the implementation of the light emitting apparatus 1 with improved stability that satisfies Equation 3.

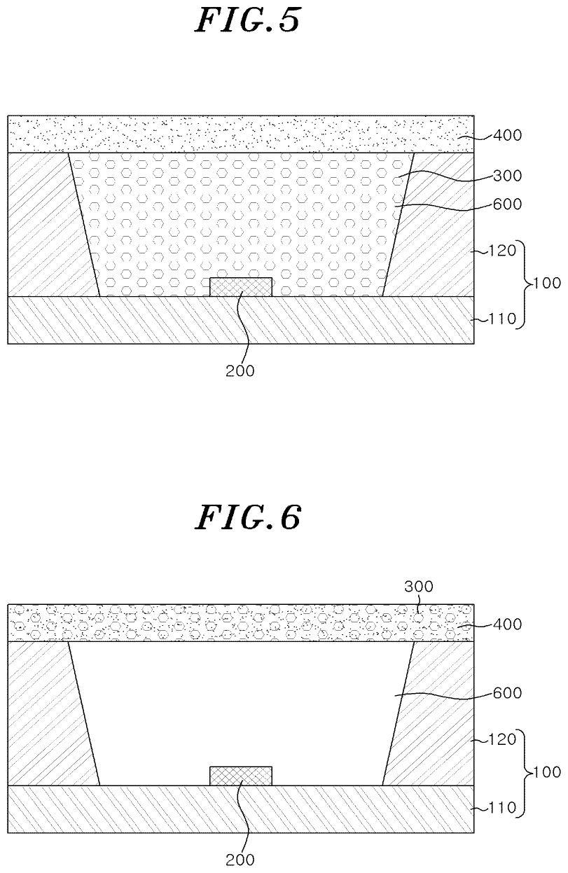

Hereinafter, a light emitting apparatus 1 according to a third embodiment of the present disclosure will be described with reference to FIGS. 5 and 6. In describing the third embodiment, there is a difference in that a molding part 600 may be further included, and the following description will focus on this difference.

The molding part 600 may be disposed in the accommodation space to cover the light-emitting source 200 and can improve the light extraction efficiency of a plurality of light-emitting sources 200. In addition, the molding part 600 may encapsulate the light-emitting source 200 and refract light emitted from the light-emitting source 200. In addition, the molding part 600 may be a light-transmitting transparent molding for transmitting light emitted from the light-emitting source 200, and for example, may be formed of a resin including at least one of a silicone series, an epoxy series, and a fluorine resin. In addition, the molding part 600 may also be formed of glass or ceramic for improving the efficiency of light emitted from the light-emitting source 200.

The wavelength converter 400 may be disposed on the upper side of the sidewall 120 and/or the molding part 600. In addition, the light-absorbing filler 300 may be disposed in at least one of the wavelength converter 400 and the molding part 600. As shown in FIG. 5, the light-absorbing filler 300 may be disposed in the molding part 600 separately from the wavelength converter 400. As such, the deterioration of the phosphor due to the light-absorbing filler 300 can be reduced, and the phosphor-converted light extraction efficiency can be increased. When the light-absorbing filler 300 is disposed in the molding part 600, the wavelength converter 400 can be disposed in a region farther away from the light-emitting source 200 than the light-absorbing filler 300. The wavelength converter 400 can be placed above the light-absorbing filler 300. In addition, as shown in FIG. 6, the light-absorbing filler 300 may be disposed in the wavelength converter 400, and may be placed on the upper side of the sidewall 120 and/or the molding part 600, Accordingly, since the light-absorbing filler 300 can absorb light, thermal stress applied to the molding part 600 may be reduced, thereby improving driving reliability.

The light-absorbing filler 300 may be disposed in at least one of the molding part 600 and the wavelength converter 400 to absorb light in a wavelength range that may be harmful to a user's body. In other words, the light-absorbing filler 300 enables the implementation of the light emitting apparatus 1 with improved stability that satisfies Equation 3.

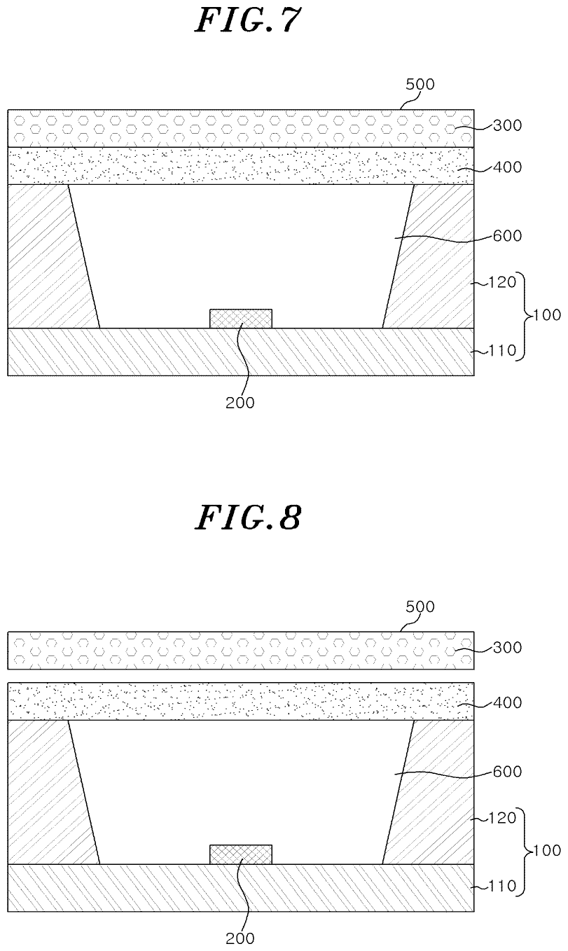

Hereinafter, a light emitting apparatus 1 according to a fourth embodiment of the present disclosure will be described with reference to FIGS. 7 to 9. In describing the fourth embodiment, there are differences in the arrangement relationship of the wavelength converter 400, the light-transmitting layer 500, and the molding part 600, and the following description will focus on these differences. Meanwhile, the light-absorbing filler 300 may be disposed in at least one of the molding part 600 and the light-transmitting layer 500.

As a first example, referring to FIG. 7, the wavelength converter 400 may be disposed in an upper region of the molding part 600, and the light-transmitting layer 500 may be disposed in an upper region of the wavelength converter 400. In addition, the light-absorbing filler 300 may be disposed in the light-transmitting layer 500. Since the light-absorbing filler 300 is disposed in the light-transmitting layer 500, it may be placed in an upper region than the wavelength converter 400 and the molding part 600. Further, light may be absorbed by the light-absorbing filler 300 after transmitting through the wavelength converter 400. Accordingly, light loss can be reduced, and phosphor conversion efficiency can be increased.

As a second example, referring to FIG. 8, the wavelength converter 400 is disposed in an upper region of the molding part 600, and the light-transmitting layer 500 is disposed in an upper region of the wavelength converter 400, wherein the wavelength converter and the light-transmitting layer 500 may be arranged to be spaced apart from each other in an up-down direction. The light-absorbing filler 300 may be disposed in the light-transmitting layer 500. In other words, the light-absorbing filler 300 may be disposed in the light-transmitting layer 500 and spaced apart from the wavelength converter 400. With such a light-absorbing filler 300, light may be absorbed by the light-absorbing filler 300 after transmitting through the wavelength converter 400, so that light loss can be reduced, re-absorption can be prevented, and phosphor conversion efficiency can be increased.

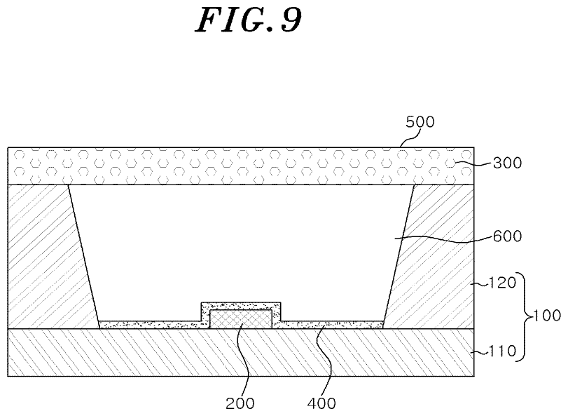

As a third example, referring to FIG. 9, the wavelength converter 400 may cover the upper surface of the base 110 and the light-emitting source 200 so that the upper surface of the base 110 and the light-emitting source 200 are spaced apart from the molding part 600. The molding part 600 may be laminated on at least one region of the wavelength converter 400 and disposed in the accommodation space. In addition, the wavelength converter 400 may be disposed on at least one region of the sidewall 120 and the molding part 600. The light-absorbing filler 300 may be disposed in the light-transmitting layer 500. In other words, the light-absorbing filler 300 may be placed on at least one region of the molding part 600 and spaced apart from the wavelength converter 400. With such a light-absorbing filler 300, light can be absorbed by the light-absorbing filler 300 after passing through the wavelength converter 400, so that light loss can be reduced, re-absorption can be prevented, and phosphor conversion efficiency can be increased.

The light-absorbing filler 300 is disposed in the light-transmitting layer 500 and can absorb light in a specific wavelength range, for example, light in a wavelength range that may be harmful to a user's body. In other words, the light-absorbing filler 300 enables the implementation of the light emitting apparatus 1 with improved stability that satisfies Equation 3.

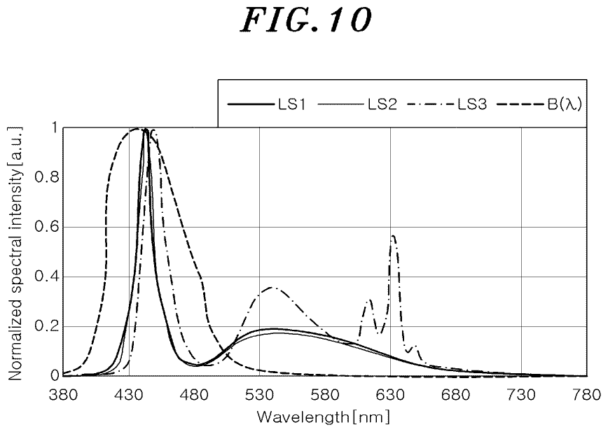

Meanwhile, FIG. 10 is a diagram showing an example of the light spectrum of the light emitting apparatus 1 of the second to fourth embodiments of the present disclosure.

In FIG. 10, LS1 represents a spectrum of light of a conventional light emitting apparatus 1 without a light-absorbing filler 300. In FIG. 10, the normalization is based on the highest peak value of spectral intensity. LS2 represents a spectrum of light emitted from a light emitting apparatus 1 including a wavelength converter 400 containing a yellow or green phosphor, and a light-absorbing filler 300. LS3 represents a spectrum of light emitted from a light emitting apparatus 1 including a wavelength converter 400 containing a yellow or green phosphor and a red phosphor (KSF), and a light-absorbing filler 300. B(λ) denotes an ocular stability function (light spectrum hazard function) for a blue light region. In LS2 and LS3, light in the 430 nm band is absorbed and reduced by the light-absorbing filler 300, so that based on the peak of blue light, a change rate on the left side of the peak may be formed to be greater than that of LS1. LS3 may have multiple peaks in the red region. That is, while the blue light hazard level of the conventional light emitting apparatus is 10 or more, it can be less than 7% in LS2 and less than 2% in LS3.

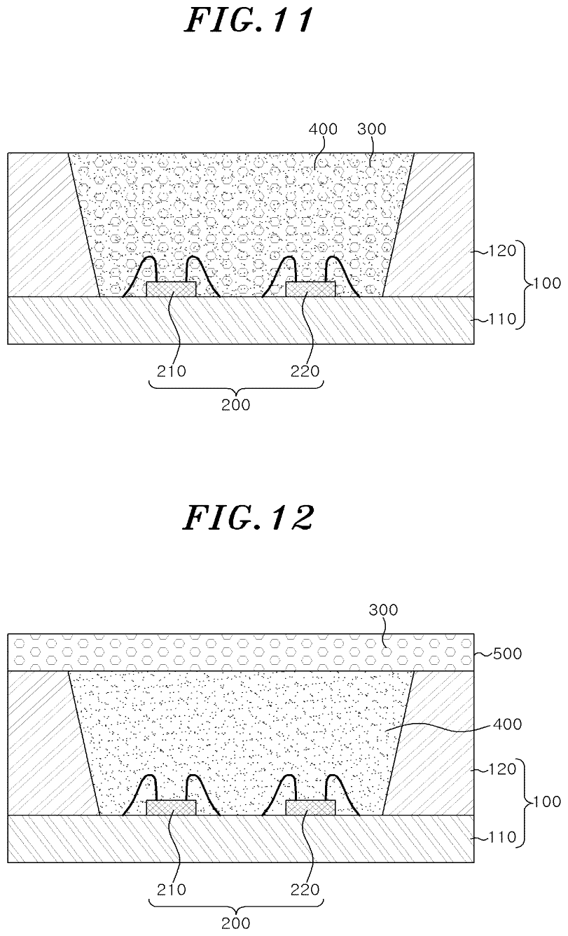

Hereinafter, a light emitting apparatus 1 according to a fifth embodiment of the present disclosure will be described with reference to FIGS. 11 to 13. In describing the fifth embodiment, there is a difference in that a plurality of light-emitting sources 200 may be provided, and the following description will focus on this difference.

The plurality of light-emitting sources 200 may include a first light-emitting source 210 and a second light-emitting source 220. The first light-emitting source 210 and the second light-emitting source 220 may have different wavelengths. For example, the first light-emitting source 210 may emit blue light. The second light-emitting source 220 may emit green light. In addition, the wavelength converter 400 may include a phosphor that emits red light.

As a first example, the wavelength converter 400 may be disposed in the accommodation space to cover at least one of the first light-emitting source 210 or the second light-emitting source 220. In addition, the light-absorbing filler 300 may be disposed in the wavelength converter 400 to increase color depth in displays. The light-absorbing filler 300 may have a higher absorption rate in a shorter wavelength region among the light emitted from the first light-emitting source 210 or the second light-emitting source 220. For example, when the first light-emitting source 210 emits blue light and the second light-emitting source 220 emits green light, the spectral difference between the native chip spectrum and the spectrum of the light-emitting device, when the wavelength converter 400 is removed, may be greater for the first light-emitting source 210 than for the second light-emitting source 220. In this case, the spectral variation of the second light-emitting source 220 may be equal to or greater than 10% and less than 50% of the spectral variation of the first light-emitting source 210. Accordingly, the amount of harmful light emitted to the user can be reduced while effectively improving light efficiency

As a second example, the wavelength converter 400 may be disposed in the accommodation space to cover the first light-emitting source 210 and the second light-emitting source 220. The light-transmitting layer 500 may be disposed in an upper region of the wavelength converter 400 or may be disposed spaced apart from the wavelength converter 400. In addition, the light-absorbing filler 300 may be disposed in the light-transmitting layer 500. A portion of the light generated from the first light-emitting source 210 and the second light-emitting source 220 may pass through the wavelength converter 400, be converted into long-wavelength light, and then transmitted through the light-transmitting layer 500 in which the light-absorbing filler 300 is disposed. By arranging the wavelength converter 400 and the light-absorbing filler 300 separately, a portion of the remaining light that is not converted by the wavelength converter 400 may be absorbed by the light-absorbing filler 300, thereby improving the conversion efficiency of the wavelength converter 400 and increasing the overall light efficiency.

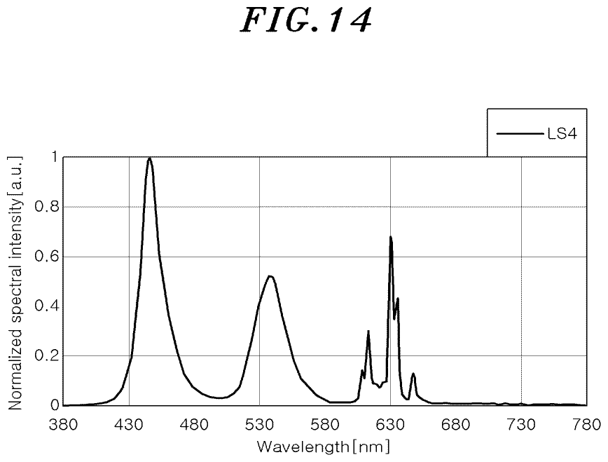

The light-absorbing filler 300 may be disposed in at least one of the wavelength converter 400 and the light-transmitting layer 500 to absorb light in a specific wavelength range among the lights emitted from the plurality of light-emitting sources 200. In other words, the light-absorbing filler 300 enables the implementation of the light emitting apparatus 1 with improved stability that satisfies Equation 3. Meanwhile, FIG. 14 is a diagram showing an example of the spectrum of light emitted from the light emitting apparatus 1 of the fifth embodiment of the present disclosure.

In FIG. 14, LS4 represents a spectrum of light emitted from the light emitting apparatus 1 including the first light-emitting source 210 that emits blue light, the second light-emitting source 220 that emits green light, the wavelength converter 400 including a red phosphor (KSF), and the light-absorbing filler 300. In LS4, the peak of the blue light may be the highest, and the peak of the green light may be smaller than the peak of the red light. In LS4, the red light may have one or more peaks. In LS4, the area under the curve for each wavelength range is largest for blue light. The area for the blue light may be narrower on the left side of the peak than the right side of the peak due to short-wavelength absorption of the light-absorbing filler 300. The area on the right side of the peak may be 10% to 20% larger than that on the left side. By designing the short-wavelength region, which has lower stability, to be smaller, it is possible to maintain the total luminous flux while improving optical stability. In addition, the change rate of the blue light peak may be made to be greater than that of the green light peak by the light-absorbing filler 300. A comparison of the light spectrum before and after removing the light-transmitting layer 500, in which the light-absorbing filler 300 is disposed, may show that the spectrum of blue light changes to a greater extent. In this case, the peak intensity variation of the blue light region may be in the range of 5% to 20%, whereas the peak intensity variation of green light may be less than 5%. Accordingly, it is possible to implement the light emitting apparatus 1 with improved stability that satisfies Equation 3, while minimizing luminous flux degradation. The full width at half maximum of the blue light may be narrower than that of the green light. The difference in the full width at half maximum between blue and green light may be 10 nm or more and less than 15 nm. Through this, the light emitting apparatus 1 with enhanced stability that satisfies Equation 3 can be realized while reducing luminous flux loss. The red light may have the narrowest full width at half maximum due to the wavelength converter 400. The blue light hazard of such a light emitting apparatus 1 may be less than 5%. Thus, the light emitting apparatus 1 with improved stability satisfying Equation 3 can be achieved. Furthermore, the light-absorbing filler 300 may absorb a portion of long-wavelength light in the green spectral region. For example, it may absorb part of the light in the wavelength range of 570 nm to 590 nm in the green peak wavelength region.

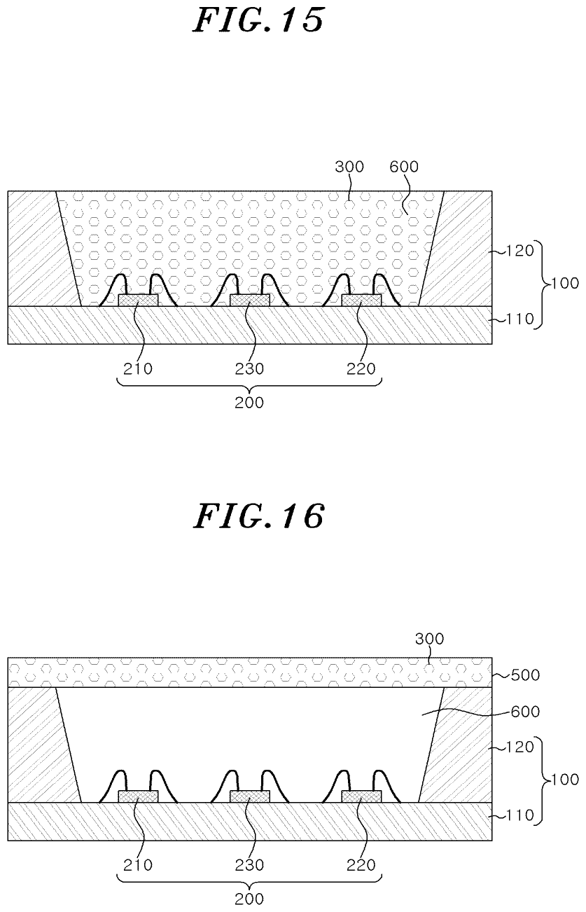

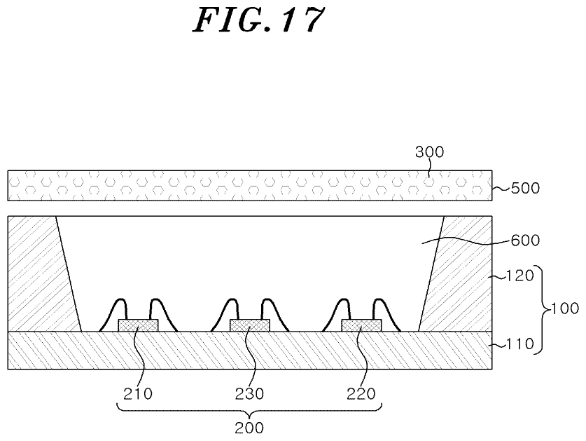

Hereinafter, a light emitting apparatus 1 according to a sixth embodiment of the present disclosure will be described with reference to FIGS. 15 to 17. In describing the fifth embodiment, a plurality of light-emitting sources 200 may include a first light-emitting source 210, a second light-emitting source 220, and a third light-emitting source 230, and at least one of the first light-emitting source 210, the second light-emitting source 220, and the third light-emitting source 230 may emit light in a different wavelength range. For example, there is a difference in that the third light-emitting source 230 emits red light, and the following description will focus on this difference.

As a first example, the first light-emitting source 210, the second light-emitting source 220, and the third light-emitting source 230 may be covered by the molding part 600. The light-absorbing filler 300 may be disposed in the molding part 600. In addition, since the wavelength converter 400 may not be provided, the process can be simplified, there is no phosphor degradation, and a more vivid color display can be achieved.

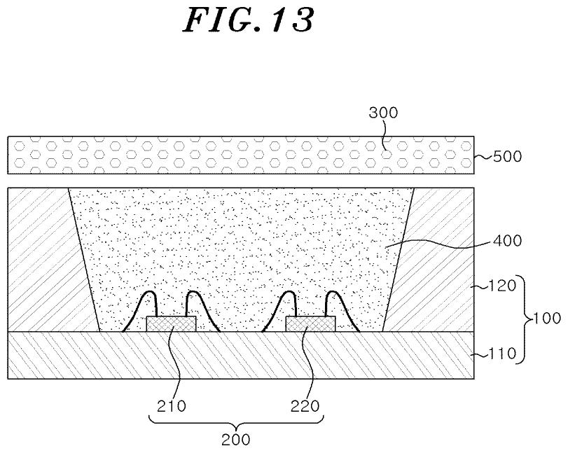

Referring to FIG. 13, as a second example, the first light-emitting source 210, the second light-emitting source 220, and the third light-emitting source 230 may be covered by the molding part 600. The light-transmitting layer 500 may be disposed on an upper region of the molding part 600 or may be disposed to be spaced upward from the molding part 600. The light-absorbing filler 300 may be disposed in the light-transmitting layer 500. In addition, since the wavelength converter 400 may not be provided, there is no phosphor degradation, and a more vivid color display can be achieved.

The light-absorbing filler 300 may be disposed in at least one of the wavelength converter 400 and the light-transmitting layer 500 to absorb light in a specific wavelength range among the lights emitted from the plurality of light-emitting sources 200. In other words, the light-absorbing filler 300 enables the implementation of the light emitting apparatus 1 with improved stability that satisfies Equation 3.

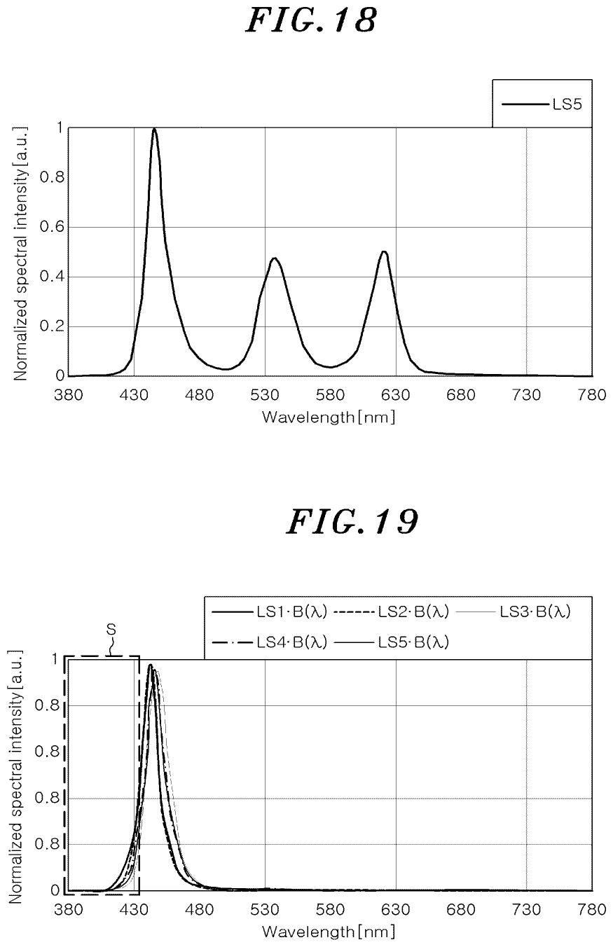

Meanwhile, FIG. 18 is an example of the spectrum of light emitted from the light emitting apparatus 1 according to the sixth embodiment. FIG. 18, the normalization is based on the highest peak value of spectral intensity

In FIG. 18, LS5 represents the light spectrum of the light emitting apparatus 1 including the first light-emitting source 210 that emits blue light, the second light-emitting source 220 that emits green light, the third light-emitting source that emits red light, and the light-absorbing filler 300. In LS5, peaks may be clearly formed for each region. There may be three or more peaks in LS5. In LS5, the full width at half maximum of blue light may be the narrowest due to the light-absorbing filler 300. For example, the full width at half maximum of a wavelength having a peak in the blue light region ranging from 430 nm to 500 nm may be 15 nm to 20 nm. The full width at half maximum of a wavelength having a peak in the green light region ranging from 500 nm to 580 nm may be 20 nm to 30 nm. The full width at half maximum of a wavelength having a peak in the red light region ranging from 580 nm to 680 nm may also be 20 nm to 30 nm. In addition, in LS5, the rate of change on the left side of the blue light peak may be greater than that on the right side. In other words, the left-side rate of change at the blue light peak in LS5 may be the greatest. Accordingly, the light emitting apparatus 1 with improved stability satisfying Equation 3 may be implemented. Furthermore, in the blue light region, the area on the left of the peak may be narrower than the area on the right of the peak. The area on the right side may be 10% to 20% greater than that on the left side. By reducing the amount of unstable short-wavelength light, it is possible to maintain overall light quantity while improving optical stability. In LS5, although the peak of the blue light may be the highest, the area on the short-wavelength side may be made narrower than the area on the long-wavelength side, thereby enabling the implementation of the light emitting apparatus 1 with improved stability that satisfies Equation 3, while maintaining overall luminous flux. In addition, the red light peak may be equal to or greater than the green light peak. The blue light hazard of the light emitting apparatus 1 may be 3% or less.

FIG. 19 is a diagram showing a graph in which the light spectrum of the light emitting apparatus 1 according to one embodiment of the present disclosure is multiplied by a light spectrum hazard function. The normalization is based on the highest peak value of spectral intensity. In other words, it is a graph in which each of the previously described LS1, LS2, LS3, LS4, and LS5 is multiplied by the light spectrum hazard function. In other words, FIG. 19 is a graph showing an area derived by Equation 1. In addition, the dotted line region B in FIG. 19 is an area calculated by Equation 2, which is 10% or less of the total area.

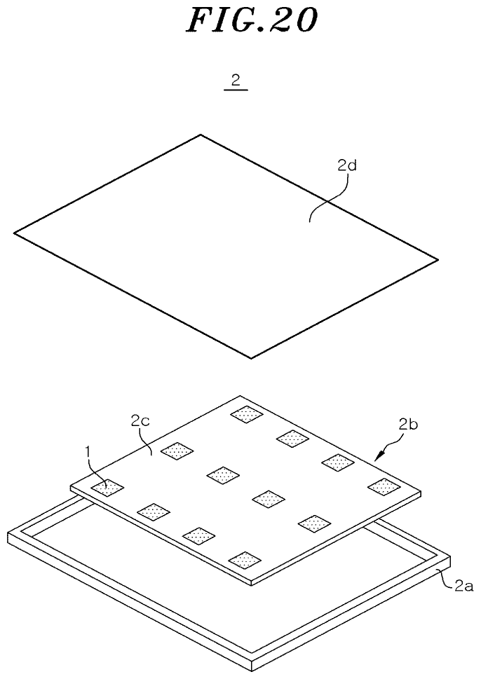

FIG. 20 is a schematic diagram for explaining a display device 2 equipped with the light emitting apparatus 1 according to one embodiment of the present disclosure.

Referring to FIG. 20, the display device 2 includes a main body 2a and a surface light source 2b mounted on the main body 2a. The main body 2a may include a high-density material with high thermal conductivity, which improves the reliability of the display device 2. A plurality of light emitting apparatuses 1 may be mounted on a substrate 2c including electrical wiring for the surface light source 2b, and each light emitting apparatus 1 may be individually driven for each region to control brightness or adjust the light-emitting region. In addition, an optical sheet 2d including at least one of a diffusion sheet for diffusing light, a polarization sheet, or a color conversion sheet may be disposed on the upper surface of the surface light source 2b. The display device 2 according to the present embodiment can have a distinct contrast ratio by reducing optical interference between the plurality of light emitting apparatuses 1 and minimizing interference between the driven regions. In addition, the display device 2 can implement a high-quality display device with distinct contrast. In addition, when the light emitting apparatus 1 is applied to the display device 2, the display device 2 with high color reproducibility and improved photobiological stability can be implemented. The light-absorbing filler 300 can absorb light in a specific wavelength range, for example, light in a wavelength range that may be harmful to a user's body. In other words, the light-absorbing filler 300 enables the implementation of the light emitting apparatus 1 with improved stability that satisfies Equation 3.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

[Explanation of Symbols]

| | |
|---|---|
| 1: light emitting apparatus | 2: display device |
| 2a: light source main body | 2b: surface light source |
| 2c: substrate | 2d: optical sheet |
| 100: substrate | 110: base |
| 120: sidewall | 200: light-emitting source |
| 210: first light-emitting source | 220: second light-emitting source |
| 230: third light-emitting source | 300: light-absorbing filler |
| 400: wavelength converter | 500: light-transmitting layer |
| 600: molding part | |

What is claimed is:

1. A light emitting apparatus, comprising:
a substrate;
a light-emitting source disposed on the substrate and configured to emit light; and
a light-absorbing filler configured to absorb light such that when an output spectrum is calculated based on a spectrum of light emitted from the light-emitting source and a preset setting function, a ratio of an area of a predetermined reference wavelength range in the output spectrum to an area of an entire wavelength range in the output spectrum is less than or equal to a threshold value,
wherein the predetermined reference wavelength range has a lower limit value smaller than a peak wavelength of the output spectrum, and an upper limit value greater than the peak wavelength of the output spectrum.

2. The light emitting apparatus of claim 1, wherein the threshold value is 10% to 15%.

3. The light emitting apparatus of claim 1, wherein the area of the entire wavelength range is calculated based on Equation 1:
$$Area of entire wavelength range = {\sum }_{a}^{b} {Φ}_{λ} \cdot B ( λ ) \cdot Δλ$$
wherein λ represents a wavelength, Φ_{λ} represents the spectral intensity of light emitted from the light-emitting source, B(λ) represents a light spectrum hazard function that is the setting function, a is a first wavelength that is the smallest in the entire wavelength range, and b is a second wavelength that is the largest in the entire wavelength range.

4. The light emitting apparatus of claim 3, wherein the area of the reference wavelength range is calculated based on Equation 2:
$$Area of reference wavelength range = {\sum }_{c}^{d} {Φ}_{λ} \cdot B ( λ ) \cdot Δλ$$
wherein λ represents the wavelength, Φ_{λ} represents the spectrum of light emitted from the light-emitting source, B(λ) represents the light spectrum hazard function, c is a first reference wavelength, and d is a second reference wavelength.

5. The light emitting apparatus of claim 4, wherein the area of the reference wavelength range and the area of the entire wavelength range satisfies Equation 3:
$$y = \frac{{\sum }_{c}^{d} {Φ}_{λ} \cdot B ( λ ) \cdot Δ λ}{{\sum }_{a}^{b} {Φ}_{λ} \cdot B ( λ ) \cdot Δ λ} \leq 10 \%$$
wherein y represents a ratio of the area of the reference wavelength range to the area of the entire wavelength range.

6. The light emitting apparatus of claim 5, wherein the first wavelength is 380 nm and the second wavelength is 780 nm.

7. The light emitting apparatus of claim 5, wherein the second wavelength is 430 nm.

8. The light emitting apparatus of claim 1, wherein a peak wavelength of the setting function is greater than a peak wavelength of the spectrum of light emitted from the light-emitting source.

9. The light emitting apparatus of claim 1, further comprising:
a wavelength converter disposed on the substrate and covering the light-emitting source; and
a light-transmitting layer disposed on at least one region of the wavelength converter.

10. The light emitting apparatus of claim 9, wherein the light-absorbing filler is disposed in at least one of the wavelength converter and the light-transmitting layer.

11. The light emitting apparatus of claim 9, wherein the wavelength converter and the light-transmitting layer are spaced apart from each other in an up-down direction.

12. The light emitting apparatus of claim 9, wherein the light-emitting source is provided as a plurality of light-emitting sources, and
the plurality of light-emitting sources include:
a first light-emitting source configured to emit blue light; and
a second light-emitting source configured to emit green light.

13. A light emitting apparatus comprising:
a substrate including a base and a sidewall extending upward from an edge of the base;
a light-emitting source disposed on the substrate and configured to emit light;
a molding part covering the light-emitting source;
a wavelength converter disposed in at least one region of the molding part and at least one region of the sidewall to convert a wavelength of light; and
a light-absorbing filler disposed in the molding part and the wavelength converter to absorb a portion of the light.

14. The light emitting apparatus of claim 13, wherein the light-emitting source is provided as a plurality of light-emitting sources, and
the plurality of light-emitting sources include:
a first light-emitting source configured to emit blue light;
a second light-emitting source configured to emit green light; and
a third light-emitting source configured to emit red light.

15. A light emitting apparatus comprising:
a substrate including a base and a sidewall extending upward from an edge of the base;
a light-emitting source disposed on the substrate and configured to emit light;
a molding part covering the light-emitting source;
a light-transmitting layer disposed in at least one region of the molding part to transmit light; and
a light-absorbing filler disposed in the light-transmitting layer to absorb a portion of the light.

16. The light emitting apparatus of claim 15, wherein the molding part and the light-transmitting layer are spaced apart from each other in an up-down direction.

17. The light emitting apparatus of claim 16, further comprising:
a wavelength converter disposed on the molding part and the sidewall to be positioned between the molding part and the light-transmitting layer and configured to convert a wavelength of light.

18. The light emitting apparatus of claim 17, wherein the light-transmitting layer and the wavelength converter are spaced apart from each other in the up-down direction.

19. The light emitting apparatus of claim 16, further comprising:
a wavelength converter covering an upper surface of the base and the light-emitting source so that the upper surface of the base and the light-emitting source are spaced apart from the molding part.

20. The light emitting apparatus of claim 16, wherein the light-emitting source is provided as a plurality of light-emitting sources, and
the plurality of light-emitting sources include:
a first light-emitting source configured to emit blue light;
a second light-emitting source configured to emit green light; and
a third light-emitting source configured to emit red light.
